(19) United States
(12) Patent Application Publication
(10) Pub. No.: US 2025/0038094 A1
(43) Pub. Date: Jan. 30, 2025

(54) SEMICONDUCTOR PACKAGE

(71) Applicant: SAMSUNG ELECTRONICS CO., LTD., SUWON-SI (KR)

(72) Inventors: Joongsun KIM, Suwon-si (KR); Minkyu KIM, Suwon-si (KR); Jeongrim SEO, Suwon-si (KR); Wonjae LEE, Suwon-si (KR); Kyuil HWANG, Suwon-si (KR)

(21) Appl. No.: 18/650,361

(22) Filed: Apr. 30, 2024

(30) Foreign Application Priority Data
Jul. 26, 2023 (KR) 10-2023-0097796

(51) Int. Cl. H01L 23/498; H01L 23/00; H01L 23/31; H01L 23/367; H01L 23/49; H01L 25/16

(52) U.S. Cl. CPC H01L 23/49838; H01L 23/3107; H01L 23/367; H01L 23/49; H01L 23/49822; H01L 25/162; H01L 23/49816; H01L 24/16; H01L 2224/16227; H01L 2924/15174

(57) ABSTRACT

A semiconductor package includes a first redistribution structure comprising a plurality of first redistribution layers. A second redistribution structure is above the first redistribution structure. The second redistribution structure comprises a plurality of second redistribution layers. A first semiconductor chip is on the first redistribution structure and is arranged between the first redistribution structure and the second redistribution structure. A conductive block directly contacts the first redistribution structure and the second redistribution structure and extends in a horizontal direction between the first redistribution structure and the second redistribution structure. A plurality of conductive posts is around the first semiconductor chip and the conductive block. The plurality of conductive posts extends in a vertical direction and directly contacts the first redistribution structure and the second redistribution structure.

### CROSS-REFERENCE TO RELATED APPLICATION

This application claims priority under 35 U.S.C. § 119 to Korean Patent Application No. 10-2023-0097796, filed on Jul. 26, 2023 in the Korean Intellectual Property Office, the disclosure of which is incorporated by reference in its entirety herein.

### 1. TECHNICAL FIELD

The present inventive concept relates to a semiconductor package. More particularly, the inventive concept relates to a fan-out semiconductor package.

### 2. DISCUSSION OF RELATED ART

Electronic devices have become increasingly compact and multifunctional and have a high capacity along with the rapid development of the electronics industry. Accordingly, highly integrated semiconductor packages are required.

Semiconductor packages including connection terminals securing connection reliability have been developed for highly integrated semiconductor chips that include a high number of connection terminals for input/output (I/O). For example, fan-out semiconductor packages capable of increasing the gap between connection terminals have been developed to prevent interference between connection terminals.

### SUMMARY

Embodiments of the present inventive concept provide a semiconductor package having increased reliability.

According to an embodiment of the present inventive concept, a semiconductor package includes a first redistribution structure comprising a plurality of first redistribution layers. A second redistribution structure is above the first redistribution structure. The second redistribution structure comprises a plurality of second redistribution layers. A first semiconductor chip is on the first redistribution structure and is arranged between the first redistribution structure and the second redistribution structure. A conductive block directly contacts the first redistribution structure and the second redistribution structure and extends in a horizontal direction between the first redistribution structure and the second redistribution structure. A plurality of conductive posts is around the first semiconductor chip and the conductive block. The plurality of conductive posts extends in a vertical direction and directly contacts the first redistribution structure and the second redistribution structure.

According to an embodiment of the present inventive concept, a semiconductor package includes a first redistribution structure comprising a first redistribution pattern comprising a first ground pattern, a first power pattern, and a first signal pattern. A second redistribution structure is above the first redistribution structure. The second redistribution structure comprises a second redistribution pattern comprising a second ground pattern, a second power pattern, and a second signal pattern. A first semiconductor chip is on the first redistribution structure and is arranged between the first redistribution structure and the second redistribution structure. A second semiconductor chip is on the second redistribution structure and comprises a heating area. A plurality of conductive blocks each has a wall shape extending in a horizontal direction between the first redistribution structure and the second redistribution structure. The plurality of conductive blocks directly contacts the first redistribution structure and the second redistribution structure. A plurality of conductive posts is around the first semiconductor chip and the plurality of conductive blocks. The plurality of conductive posts directly contacts the first redistribution structure and the second redistribution structure. The plurality of conductive posts each has a pillar shape extending in a vertical direction. An encapsulation material is between the first redistribution structure and the second redistribution structure. The encapsulation material surrounds the first semiconductor chip, the plurality of conductive blocks, and the plurality of conductive posts.

According to an embodiment of the present inventive concept, a semiconductor package includes a first redistribution structure comprising a first redistribution pattern comprising a first ground pattern, a first power pattern, and a first signal pattern. A second redistribution structure is above the first redistribution structure. The second redistribution structure comprises a second redistribution pattern comprising a second ground pattern, a second power pattern, and a second signal pattern. A first semiconductor chip is on the first redistribution structure and is arranged between the first redistribution structure and the second redistribution structure. A second semiconductor chip is on the second redistribution structure and comprises a heating area. A plurality of conductive blocks extends in a horizontal direction between the first redistribution structure and the second redistribution structure. The plurality of conductive blocks directly contacts the first redistribution structure and the second redistribution structure. The plurality of conductive blocks comprises a heat dissipation block, a power block, and a shielding block. A plurality of conductive posts is around the first semiconductor chip and the plurality of conductive blocks. The plurality of conductive posts extends in a vertical direction and directly contacts the first redistribution structure and the second redistribution structure.

### BRIEF DESCRIPTION OF THE DRAWINGS

Embodiments will be more clearly understood from the following detailed description taken in conjunction with the accompanying drawings in which:

FIG. 1 is a plan view of a semiconductor package at a first vertical level according to an embodiment of the present inventive concept;

FIG. 2A is a cross-sectional view of the semiconductor package taken along line X1-X1′ in FIG. 1 according to an embodiment of the present inventive concept;

FIG. 2B is a cross-sectional view of the semiconductor package taken along line Y1-Y1′ in FIG. 1 according to an embodiment of the present inventive concept;

FIG. 3A is a plan view illustrating a semiconductor package at a second vertical level, according to an embodiment of the present inventive concept;

FIG. 3B is a plan view illustrating a semiconductor package at a third vertical level, according to an embodiment of the present inventive concept;

FIG. 3C is a plan view of a redistribution pattern of a semiconductor package according to an embodiment of the present inventive concept;

FIG. 4A is a plan view illustrating a semiconductor package at a first vertical level according to an embodiment of the present inventive concept;

FIG. 4B is a perspective view illustrating a configuration of a semiconductor package according to an embodiment of the present inventive concept;

FIGS. 5A to 5C are plan views of a semiconductor package at the first vertical level, according to embodiments of the present inventive concept; and

FIG. 6 shows plan views of a semiconductor package at the first vertical level, according to some embodiments of the present inventive concept.

### DETAILED DESCRIPTION OF EMBODIMENTS

Hereinafter, embodiments of the present inventive concept are described in detail with reference to the accompanying drawings. In the drawing, like reference characters denote like elements, and redundant descriptions thereof will be omitted.

Herein, a vertical direction may be defined as the Z direction and a horizontal direction may be defined as being orthogonal to the Z direction. A first horizontal direction and a second horizontal direction may be defined as crossing each other. The first horizontal direction may be referred to as the X direction and the second horizontal direction may be referred to as the Y direction. A vertical level may refer to the level of a height in the vertical direction (e.g., the Z direction). The horizontal width of an element may refer to a length of the element in a horizontal direction (e.g., the X and/or Y directions). The vertical length of an element may refer to the length of the element in the vertical direction (e.g., the Z direction).

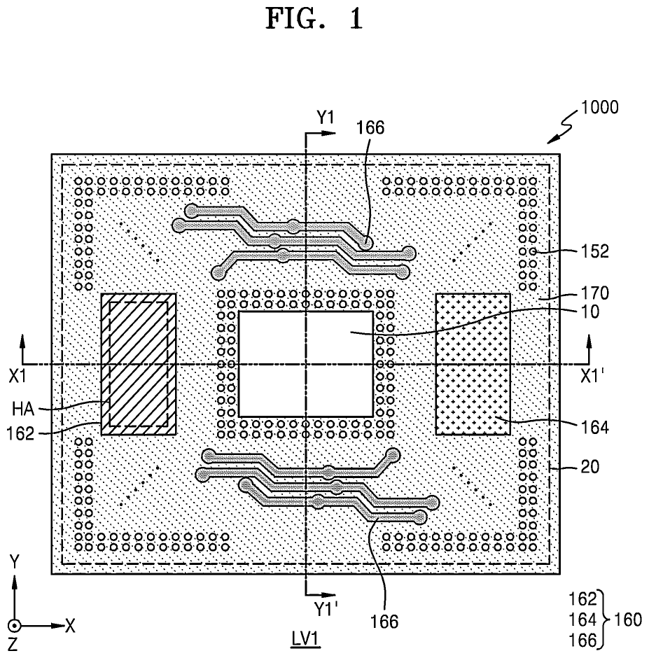

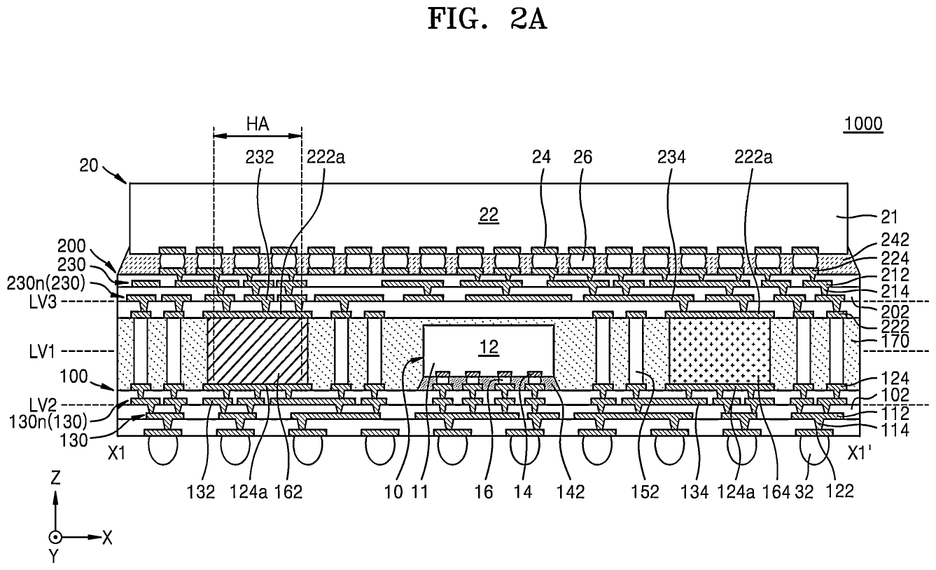

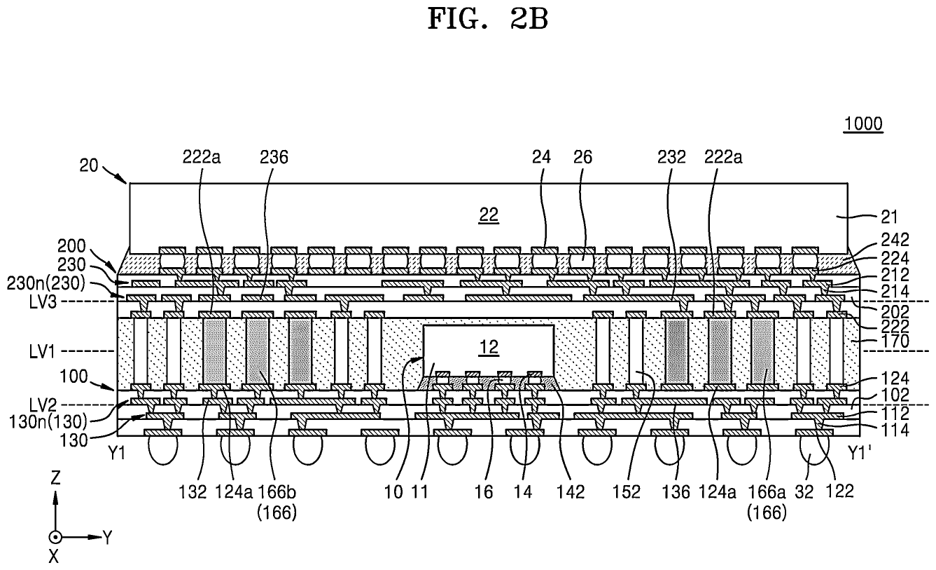

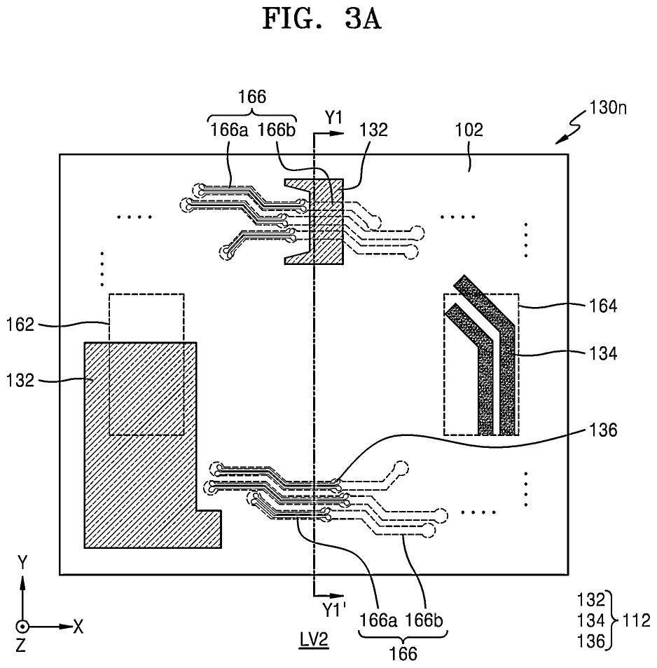

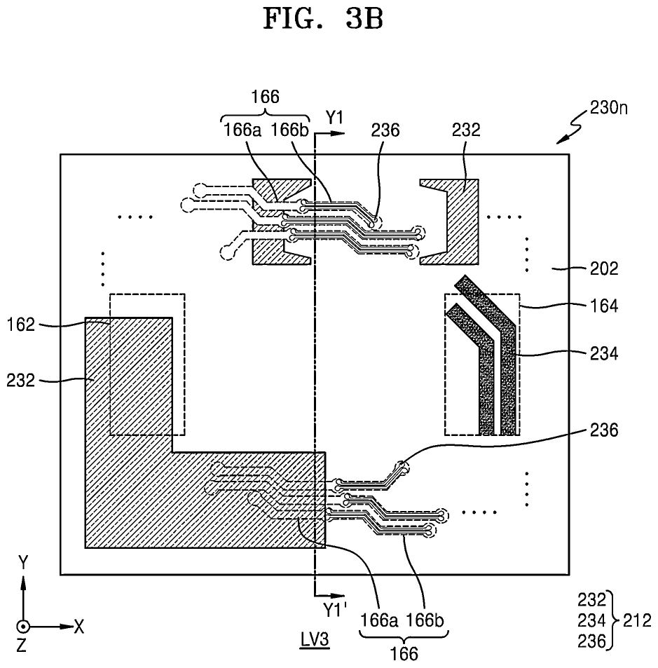

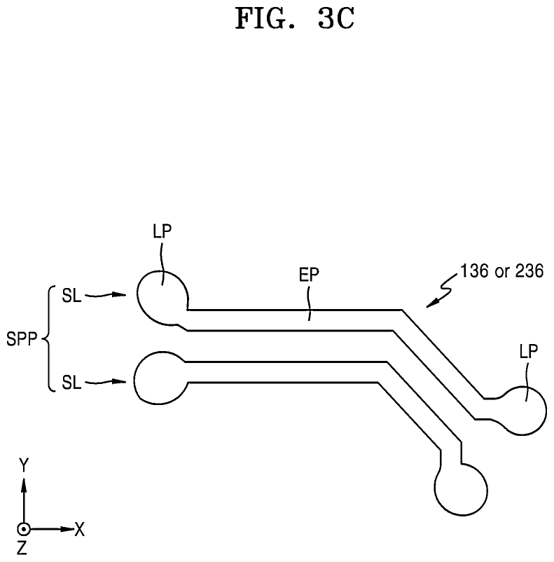

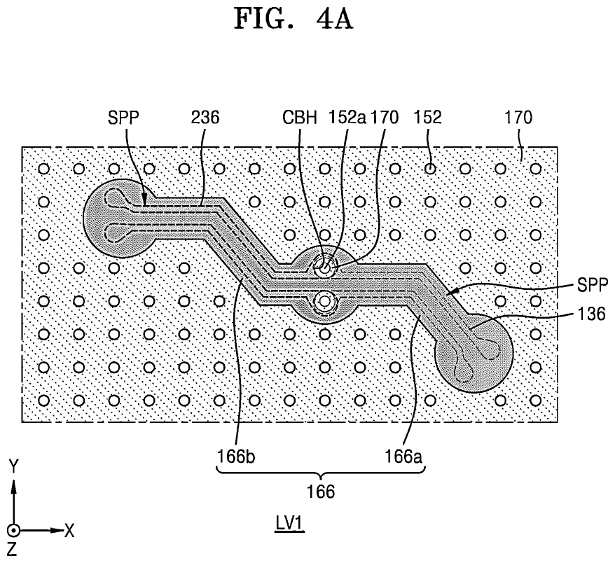

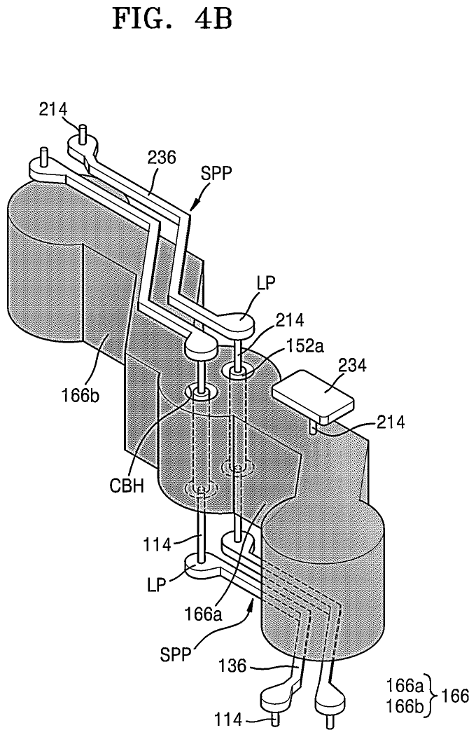

FIG. 1 is a plan view of a semiconductor package 1000 at a first vertical level LV1 in FIGS. 2A and 2B, according to embodiments. FIG. 2A is a cross-sectional view of the semiconductor package 1000 taken along line X1-X1′ in FIG. 1. FIG. 2B is a cross-sectional view of the semiconductor package 1000 taken along line Y1-Y1′ in FIG. 1. FIG. 3A is a plan view illustrating the semiconductor package 1000 of FIGS. 1 to 2B at a second vertical level LV2 in FIGS. 2A and 2B. FIG. 3B is a plan view illustrating the semiconductor package 1000 of FIGS. 1 to 2B at a third vertical level LV3 in FIGS. 2A and 2B. FIG. 3C is a plan view of a redistribution pattern of the semiconductor package 1000, according to embodiments. FIG. 4A is a partial plan view illustrating the semiconductor package 1000 of FIGS. 1 to 2B at the first vertical level LV1 in FIGS. 2A and 2B. FIG. 4B is a perspective view illustrating a configuration of the semiconductor package 1000 of FIGS. 1 to 2B.

Referring to FIGS. 1 to 4B, the semiconductor package 1000 may include a first redistribution structure 100, a second redistribution structure 200 on the first redistribution structure 100, at least one first semiconductor chip 10 mounted on the first redistribution structure 100, a plurality of conductive blocks 160 between the first redistribution structure 100 and the second redistribution structure 200 (e.g., in the Z direction), a plurality of conductive posts 152 around the first semiconductor chip 10 and the conductive blocks 160, and at least one second semiconductor chip 20 mounted on the second redistribution structure 200.

In some embodiments, the semiconductor package 1000 may be a fan-out semiconductor package, in which the horizontal width and plane area of the first redistribution structure 100 are respectively greater than the horizontal width and plane area of the footprint of the first semiconductor chip 10. In some embodiments, the semiconductor package 1000 may correspond to a fan-out wafer-level package (FOWLP) or a fan-out panel-level package (FOPLP).

According to an embodiment, at least one of the first redistribution structure 100 and the second redistribution structure 200 may be formed by a redistribution process. The first redistribution structure 100 and the second redistribution structure 200 may be respectively referred to as a first wiring structure and a second wiring structure or a lower redistribution structure and an upper redistribution structure.

According to an embodiment, the first redistribution structure 100 may include a plurality of first redistribution layers 130 stacked in the vertical direction (e.g., the Z direction), a plurality of first redistribution vias 114, and a first redistribution insulating layer 102 surrounding the first redistribution layers 130 and the first redistribution vias 114.

According to an embodiment, the first redistribution layers 130 may be separated from each other in the vertical direction (e.g., the Z direction) and the first redistribution insulating layer 102 may be between the first redistribution layers 130 (e.g., in the Z direction). According to an embodiment, each of the first redistribution vias 114 may extend in the vertical direction (e.g., the Z direction) and may be in direct contact with and directly connected to respective portions of first redistribution layers 130 at different vertical levels. According to an embodiment, each of the first redistribution layers 130 may include a plurality of first redistribution patterns 112. For example, in an embodiment each of the first redistribution patterns 112 may have a dot shape, a planar shape, or a line shape. In an embodiment, the first redistribution patterns 112 of each of the first redistribution layers 130 may be on the same plane as each other, respectively (e.g., in the Z direction).

In some embodiments, the first redistribution insulating layer 102 may include a single layer or a plurality of layers. For example, in an embodiment the first redistribution insulating layer 102 may be formed from a photo-imageable dielectric (PID) or photosensitive polyimide (PSPI). However, embodiments of the present inventive concept are not necessarily limited thereto.

In some embodiments, each of the first redistribution layers 130 and the first redistribution vias 114 may include, but is not necessarily limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Bc), gallium (Ga), or ruthenium (Ru), or an alloy thereof. In some embodiments, each of the first redistribution layers 130 and the first redistribution vias 114 may be formed by stacking metal or a metal alloy on a seed layer including copper, titanium, titanium nitride, or titanium tungsten.

In some embodiments, each of the first redistribution vias 114 may have a tapered shape having a horizontal width increasing upwards (e.g., in the Z direction). For example, the horizontal width of each of the first redistribution vias 114 may increase as a distance towards the first semiconductor chip 10 decreases.

In some embodiments, at least a portion of each of the first redistribution layers 130 may be simultaneously and integrally formed with some of the first redistribution vias 114. For example, in an embodiment each of at least some of the first redistribution patterns 112 may be simultaneously and integrally formed with a first redistribution via 114 that is in direct contact with the bottom surface of each first redistribution pattern 112.

According to an embodiment, a plurality of first bottom connection pads 122 may be on the bottom of the first redistribution structure 100. According to an embodiment, some of the first redistribution vias 114 may pass through the first redistribution insulating layer 102 in the vertical direction (e.g., the Z direction) and be in direct contact with and directly connected to first bottom connection pads 122, respectively, and in direct contact with and directly connected to a bottommost first redistribution layer 130 closest to the bottom of the first redistribution structure 100 among the first redistribution layers 130.

According to an embodiment, a plurality of first top connection pads 124 may be on the top surface of the first redistribution structure 100 and may comprise a portion of the first redistribution structure 100. According to an embodiment, some of the first redistribution vias 114 may pass through the first redistribution insulating layer 102 (e.g., in the Z direction) and be in direct contact with and directly connected to the first top connection pads 124, respectively, and in direct contact with and directly connected to a topmost first redistribution layer 130 closest to the top of the first redistribution structure 100 among the first redistribution layers 130. According to an embodiment, the first top connection pads 124 may be on the top surface of the first redistribution insulating layer 102.

In some embodiments, the first bottom connection pads 122 and the first top connection pads 124 may include, but is not necessarily limited to, metal or a metal alloy.

In some embodiments, each of the first bottom connection pads 122 and the first top connection pads 124 may be simultaneously and integrally formed with a first redistribution via 114 connected thereto. In some embodiments, each of the first bottom connection pads 122 and the first top connection pads 124 may include a different material than a first redistribution via 114 connected thereto.

Although it is illustrated in FIGS. 2A and 2B that the side surfaces of the first bottom connection pads 122 are covered with the first redistribution insulating layer 102 and the side surfaces of the first top connection pads 124 are not covered with the first redistribution insulating layer 102, embodiments of the present inventive concept are not necessarily limited thereto. For example, in an embodiment the side surfaces of the first bottom connection pads 122 may be exposed without being covered with the first redistribution insulating layer 102. For example, the side surfaces of the first top connection pads 124 may be covered with the first redistribution insulating layer 102.

Although it is illustrated in FIGS. 2A and 2B that the first redistribution structure 100 includes two first redistribution layers 130, embodiments of the present inventive concept are not necessarily limited thereto. For example, the first redistribution structure 100 may include one first redistribution layer 130 or at least three first redistribution layers 130.

According to an embodiment, a plurality of external connection terminals 32 may be respectively attached to the bottom surfaces of the first bottom connection pads 122. The external connection terminals 32 may connect the semiconductor package 1000 to the outside (e.g., to an external device). In some embodiments, each of the external connection terminals 32 may include a bump or a solder ball.

According to an embodiment, a plurality of first chip connectors 16, the conductive blocks 160, and the conductive posts 152 may be in direct contact with and directly connected to the top surfaces of the first top connection pads 124, respectively. For example, a plurality of lower block pads 124a among the first top connection pads 124 may be in direct contact with and directly connected to the conductive blocks 160, respectively.

According to an embodiment, at least one first semiconductor chip 10 may be attached onto the first redistribution structure 100. In an embodiment, the first semiconductor chip 10 may include a first semiconductor substrate 11 having an active surface and an inactive surface opposite to the active surface (e.g., in the Z direction), a first semiconductor device 12 on the active surface of the first semiconductor substrate 11, and a plurality of first chip pads 14 on a first surface of the first semiconductor chip 10. Herein, the first surface of the first semiconductor chip 10 is opposite to a second surface of the first semiconductor chip 10 (e.g., in the Z direction). The second surface of the first semiconductor chip 10 may refer to the inactive surface of the first semiconductor substrate 11. The active surface of the first semiconductor substrate 11 is very close to the first surface of the first semiconductor chip 10 and thus not separately illustrated from the first surface of the first semiconductor chip 10 in the drawings.

In some embodiments, the first semiconductor chip 10 may be attached to the top surface of the first redistribution structure 100 in a face-down manner such that the first surface of the first semiconductor chip 10 faces the first redistribution structure 100. In this embodiment, the first surface of the first semiconductor chip 10 may be referred to as the bottom surface of the first semiconductor chip 10 and the second surface of the first semiconductor chip 10 may be referred to as the top surface of the first semiconductor chip 10. Herein, the top surface refers to a surface facing upwards in the drawings and the bottom surface refers to a surface facing downwards in the drawings, unless stated otherwise.

According to an embodiment, the first chip connectors 16 may be between the first chip pads 14 of the first semiconductor chip 10 and at least some of the first top connection pads 124 of the first redistribution structure 100 (e.g., in the third direction Z). For example, the first chip connectors 16 may be in direct contact with the first chip pads 14, respectively, and in direct contact with a plurality of first top connection pads 124, respectively. The first semiconductor chip 10 may be electrically connected to the first redistribution structure 100 through the first chip connectors 16. According to an embodiment, a first underfill 142 may be interposed between the first semiconductor chip 10 and the first redistribution structure 100. The first underfill 142 may surround the first chip connectors 16. In an embodiment, the first underfill 142 may be made of, for example, epoxy resin. In some other embodiments, a non-conductive film may be interposed between the first semiconductor chip 10 and the first redistribution structure 100. In some embodiments, each of the first chip connectors 16 may include a solder ball or a micro-bump. In some embodiments, each of the first chip connectors 16 may include, but is not necessarily limited to, a conductive material, such as copper (Cu), aluminum (Al), silver (Ag), tin (Sn), gold (Au), or solder.

In some embodiments, the first semiconductor substrate 11 may include a semiconductor material, such as silicon (Si) or germanium (Ge). In some embodiments, the first semiconductor substrate 11 may include a compound semiconductor, such as silicon carbide (SiC), gallium arsenide (GaAs), indium arsenide (InAs), or indium phosphide (InP). The first semiconductor substrate 11 may include a conductive region, such as an impurity-doped well. The first semiconductor substrate 11 may have various isolation structures such as a shallow trench isolation (STI) structure.

In some embodiments, the first semiconductor device 12 including various kinds of individual devices may be on the active surface of the first semiconductor substrate 11. In an embodiment, the individual devices may include various microelectronic devices, such as a metal-oxide-semiconductor field effect transistor (MOSFET) such as a complementary metal-oxide-semiconductor (CMOS) transistor, a system large scale integration (LSI), an active element, and a passive element. The individual devices may be electrically connected to the conductive region of the first semiconductor substrate 11. The first semiconductor device 12 may further include a conductive plug or conductive wiring, which electrically connects the individual devices or at least two of the individual devices to the conductive region of the first semiconductor substrate 11. In an embodiment, each of the individual devices may be electrically separated from other adjacent individual devices by an insulating film.

In some embodiments, the first semiconductor chip 10 may include a memory chip or a logic chip. For example, the memory chip may include a volatile memory chip, such as a dynamic random access memory (DRAM) chip or a static RAM (SRAM) chip, or a non-volatile memory chip, such as a phase-change RAM (PRAM) chip, a magnetoresistive RAM (MRAM) chip, a ferroelectric RAM (FeRAM) chip, or a resistive RAM (RRAM) chip. For example, the logic chip may include a microprocessor, such as a central processing unit (CPU), a graphics processing unit (GPU), or an application processor (AP), an analog device, or a digital signal processor.

In some embodiments, the first semiconductor chip 10 may function as a bridge chip, which electrically connects the first redistribution structure 100 to the second semiconductor chip 20 mounted on the second redistribution structure 200. In this embodiment, the first semiconductor chip 10 may be in direct contact with and connected to the second redistribution structure 200 through a separate conductive connector thereof.

According to an embodiment, the second redistribution structure 200 may include a plurality of second redistribution layers 230 stacked in the vertical direction (e.g., the Z direction), a second redistribution insulating layer 202 surrounding the second redistribution layers 230, and a plurality of second redistribution vias 214 each passing through the second redistribution insulating layer 202 to be in contact with and connected to the second redistribution layers 230 at different vertical levels.

According to an embodiment, each of the second redistribution layers 230 may include a plurality of second redistribution patterns 212. For example, in an embodiment each of the second redistribution patterns 212 may have a dot shape, a planar shape, or a line shape. The second redistribution patterns 212 of each of the second redistribution layers 230 may be on the same plane as each other, respectively (e.g., in the Z direction). In some embodiments, the second redistribution insulating layer 202 may include a single layer or a plurality of layers and may be formed from a PID or PSPI. However, embodiments of the present inventive concept are not necessarily limited thereto.

In some embodiments, each of the second redistribution layers 230 and the second redistribution vias 214 may include, but is not necessarily limited to, metal or a metal alloy. In some embodiments, each of the second redistribution layers 230 and the second redistribution vias 214 may be formed by stacking metal or a metal alloy on a seed layer.

In some embodiments, at least a portion of each of the second redistribution layers 230 may be simultaneously and integrally formed with some of the second redistribution vias 214. For example, each of at least some of the second redistribution patterns 212 may be simultaneously and integrally formed with a second redistribution via 214 that is in direct contact with the bottom surface of each second redistribution pattern 212.

In some embodiments, each of the second redistribution vias 214 may have a tapered shape having a horizontal width decreasing downwards (e.g., in the Z direction). For example, the horizontal width of each of the second redistribution vias 214 may decrease as a distance towards the first semiconductor chip 10 decreases. The first redistribution vias 114 and the second redistribution vias 214 may extend in the same direction and have horizontal widths increasing or decreasing in the same direction. For example, each of the first redistribution vias 114 and the second redistribution vias 214 may have a tapered shape, which extends in a direction from the first redistribution structure 100 towards the second redistribution structure 200 and has a horizontal width increasing in the direction, or a tapered shape, which extends in a direction from the second redistribution structure 200 towards the first redistribution structure 100 and has a horizontal width decreasing in the direction.

According to an embodiment, a plurality of second bottom connection pads 222 may be on the bottom of the second redistribution structure 200 and may comprise a portion of the second redistribution structure 220. According to an embodiment, some of the second redistribution vias 214 may pass through the second redistribution insulating layer 202 in the vertical direction (e.g., the Z direction) and be in direct contact with and directly connected to second bottom connection pads 222, respectively, and in direct contact with and directly connected to a bottommost second redistribution layer 230 closest to the bottom of the second redistribution structure 200 among the second redistribution layers 230.

According to an embodiment, a plurality of second top connection pads 224 may be on the top surface of the second redistribution structure 200. According to an embodiment, some of the second redistribution vias 214 may pass through the second redistribution insulating layer 202 and be in direct contact with and directly connected to the second top connection pads 224, respectively, and in direct contact with and directly connected to a topmost second redistribution layer 230 closest to the top of the second redistribution structure 200 among the second redistribution layers 230. According to an embodiment, the second top connection pads 224 may be on the top surface of the second redistribution insulating layer 202.

In some embodiments, the second bottom connection pads 222 and second top connection pads 224 may include, but is not necessarily limited to, metal or a metal alloy.

In some embodiments, each of the second bottom connection pads 222 and the second top connection pads 224 may be simultaneously and integrally formed with at least one second redistribution via 214 connected thereto. In some embodiments, each of the second bottom connection pads 222 and the second top connection pads 224 may include a different material than at least one second redistribution via 214 connected thereto.

Although it is illustrated in FIGS. 2A and 2B that the side surfaces of the second bottom connection pads 222 are covered with the second redistribution insulating layer 202 and the side surfaces of the second top connection pads 224 are not covered with the second redistribution insulating layer 202, embodiments of the present inventive concept are not necessarily limited thereto. For example, in an embodiment the side surfaces of the second bottom connection pads 222 may be exposed without being covered with the second redistribution insulating layer 202. For example, the side surfaces of the second top connection pads 224 may be covered with the second redistribution insulating layer 202.

Although it is illustrated in FIGS. 2A and 2B that the second redistribution structure 200 includes two second redistribution layers 230, embodiments of the present inventive concept are not necessarily limited thereto. For example, in an embodiment the second redistribution structure 200 may include one second redistribution layer 230 or at least three second redistribution layers 230.

According to an embodiment, the conductive blocks 160 and the conductive posts 152 may be in direct contact with and directly connected to the bottom surfaces of the second bottom connection pads 222, respectively. For example, a plurality of upper block pads 222a among the second bottom connection pads 222 may be in direct contact with and directly connected to the conductive blocks 160, respectively.

According to an embodiment, a plurality of second chip connectors 26 may be respectively in direct contact with and directly connected to the top surfaces of at least some of the second top connection pads 224.

In some embodiments, at least one second semiconductor chip 20 may be attached onto the second redistribution structure 200. The second semiconductor chip 20 may include a second semiconductor substrate 21 having an active surface and an inactive surface opposite to the active surface (e.g., in the Z direction), a second semiconductor device 22 on the active surface of the second semiconductor substrate 21, and a plurality of second chip pads 24 on a first surface of the second semiconductor chip 20.

In some embodiments, the second semiconductor chip 20 may be attached to the top surface of the second redistribution structure 200 in a face-down manner such that the first surface of the second semiconductor chip 20 faces the second redistribution structure 200.

According to an embodiment, the second chip connectors 26 may be between the second chip pads 24 of the second semiconductor chip 20 and at least some of the second top connection pads 224 of the second redistribution structure 200 (e.g., in the Z direction). For example, the second chip connectors 26 may be respectively in direct contact with the second chip pads 24 and respectively in direct contact with the second top connection pads 224. The second semiconductor chip 20 may be electrically connected to the second redistribution structure 200 through the second chip connectors 26. According to an embodiment, a second underfill 242 may be interposed between the second semiconductor chip 20 and the second redistribution structure 200. The second underfill 242 may surround the second chip connectors 26. In an embodiment, the second underfill 242 may be made of, for example, epoxy resin. However, embodiments of the present inventive concept are not necessarily limited thereto. For example, in some embodiments, a non-conductive film may be interposed between the second semiconductor chip 20 and the second redistribution structure 200. For example, each of the second chip connectors 26 may include, but is not necessarily limited to, a solder ball or a micro-bump.

In some embodiments, the second semiconductor chip 20 may include a memory chip or a logic chip. For example, the memory chip may include a volatile memory chip, such as a DRAM chip or an SRAM chip, or a non-volatile memory chip, such as a PRAM chip, an MRAM chip, an FeRAM chip, or an RRAM chip. For example, the logic chip may include a microprocessor, such as a CPU, a GPU, or an AP, an analog device, or a digital signal processor. In some embodiments, the first semiconductor chip 10 may correspond to a memory chip and the second semiconductor chip 20 may correspond to a logic chip. However, embodiments of the present inventive concept are not necessarily limited thereto.

In some embodiments, the second semiconductor chip 20 may correspond to a chip structure, which includes a plurality of individual chips arranged in the horizontal direction (e.g., the X direction and/or the Y direction) and/or the vertical direction (e.g., the Z direction).

According to an embodiment, the conductive blocks 160 may be between the first redistribution structure 100 and the second redistribution structure 200 (e.g., in the Z direction) and may extend in the horizontal direction (e.g., the X direction and/or the Y direction). The conductive blocks 160 may be spaced apart from each other. According to an embodiment, the bottom surfaces of the conductive blocks 160 may be respectively in direct contact with the lower block pads 124a and the top surfaces of the conductive blocks 160 may be respectively in direct contact with the upper block pads 222a. According to an embodiment, the conductive blocks 160 may be electrically connected to the first redistribution structure 100 and the second redistribution structure 200. According to an embodiments, each of the conductive blocks 160 may have a wall shape, which has a line-shaped horizontal cross-section and extends in the horizontal direction (e.g., the X direction and/or the Y direction), or a plate shape, which has a planar horizontal cross-section and extends in the horizontal direction (e.g., the X direction and/or the Y direction).

According to an embodiment, the conductive posts 152 may be positioned around the conductive blocks 160 and the first semiconductor chip 10. The conductive posts 152 may be spaced apart from each other (e.g., in the X direction and/or the Y direction) and spaced apart from the first semiconductor chip 10 and the conductive blocks 160. In some embodiments, the conductive posts 152 may extend in the vertical direction (e.g., the Z direction) between the first redistribution structure 100 and the second redistribution structure 200 and may be respectively in direct contact with some of the first top connection pads 124 and respectively in direct contact with some of the second bottom connection pads 222. For example, the conductive posts 152 may electrically connect the first redistribution structure 100 to the second redistribution structure 200. In some embodiments, each of the conductive posts 152 may have a pillar shape, which has a circular, an oval, or a polygonal horizontal cross-section and extends in the vertical direction (e.g., the Z direction). However, embodiments of the present inventive concept are not necessarily limited thereto.

In some embodiments, according to a plan view, the conductive posts 152 may each have a dot shape and may surround the conductive blocks 160 each having a planar or line shape. For example, the conductive posts 152 may be disposed between the conductive blocks 160 and between the conductive blocks 160 and the first semiconductor chip 10 (e.g., in the X and/or Y directions).

In some embodiments, the volumes of the conductive blocks 160 may be different from each other and the volumes of the conductive posts 152 may be substantially uniform. In some embodiments, the volume of each of the conductive blocks 160 may be in a range of about 20 to about 800 times larger than the volume of each of the conductive posts 152.

In some embodiments, the length of each of the conductive blocks 160 in the vertical direction (e.g., the Z direction) may be equal to the length of each of the conductive posts 152 in the vertical direction (the Z direction). For example, in an embodiment the top surface of the conductive blocks 160 may be at the same vertical level as the top surface of the conductive posts 152 and the bottom surface of the conductive blocks 160 may be at the same vertical level as the bottom surface of the conductive posts 152.

In some embodiments, the conductive blocks 160 and the conductive posts 152 may be formed together in the same process.

In some embodiments, each of the conductive blocks 160 and the conductive posts 152 may include copper (Cu), copper-tin (CuSn), copper-manganese (CuMg), copper-nickel (CuNi), copper-zinc (CuZn), copper-lead (CuPb), copper-gold (CuAu), copper-tungsten (CuW), tungsten (W), or an alloy thereof. However, embodiments of the present inventive concept are not necessarily limited thereto.

In some embodiments, an encapsulation material 170 surrounding the first semiconductor chip 10, the conductive blocks 160, and the conductive posts 152 may be disposed between the first redistribution structure 100 and the second redistribution structure 200 (e.g., in the Z direction). For example, the encapsulation material 170 may protect the first semiconductor chip 10 from external impact, such as contamination and shock.

According to an embodiment, each of the first semiconductor chip 10 and the conductive blocks 160 may be separated from the conductive posts 152 by the encapsulation material 170. For example, the conductive posts 152 may be separated from each other and from the conductive blocks 160 in the horizontal direction (e.g., the X direction and/or the Y direction) with the encapsulation material 170 disposed directly therebetween.

In some embodiments, the encapsulation material 170 may include thermosetting resin such as epoxy resin, thermoplastic resin such as polyimide, or resin including a reinforcing material such as an inorganic filler. For example, in an embodiment the encapsulation material 170 may include an Ajinomoto build-up film (ABF), flame retardant 4 (FR-4), or bismaleimide triazine (BT). A molding material such as an epoxy mold compound or a photosensitive material such as a photo-imageable encapsulant (PIE) may be used as the encapsulation material 170. However, embodiments of the present inventive concept are not necessarily limited thereto.

According to an embodiment, the lower block pads 124a may vertically overlap the conductive blocks 160, respectively, and the upper block pads 222a may vertically overlap the conductive blocks 160, respectively. In some embodiments, each of the conductive blocks 160 may be in direct contact with one of the upper block pads 222a and one of the lower block pads 124a. In some embodiments, one conductive block 160 may be in direct contact with a plurality of upper block pads 222a or a plurality of lower block pads 124a.

For example, one of the conductive blocks 160 (hereinafter, referred to as the first conductive block 160) may be in direct contact with one of the lower block pads 124a (hereinafter referred to as the first lower block pad 124a) and one of the upper block pads 222a (hereinafter, referred to as the first upper block pad 222a).

In some embodiments, each of the first lower block pad 124a and the first upper block pad 222a may have a planar shape similar to the planar shape of the first conductive block 160 and overlap the first conductive block 160 in the vertical direction (e.g., the Z direction). For example, the first upper block pad 222a, the first conductive block 160, and the first lower block pad 124a may be aligned with one another in the vertical direction (e.g., the Z direction). In some embodiments, the first conductive block 160 may have a plate shape and each of the first upper block pad 222a and the first lower block pad 124a may have a planar shape according to a plan view in correspondence to the first conductive block 160. In some embodiments, the first conductive block 160 may have a wall shape and each of the first upper block pad 222a and the first lower block pad 124a may have a line shape according to a plan view in correspondence to the first conductive block 160.

Referring to FIGS. 2A, 2B, and 3A, a first adjacent redistribution layer 130n positioned closest to the conductive blocks 160 (e.g., in the Z direction) among the first redistribution layers 130 may be at the second vertical level LV2. According to an embodiment, the first redistribution patterns 112 of the first adjacent redistribution layer 130n may include a first ground pattern 132, a first power pattern 134, and a first signal pattern 136. According to an embodiment, the first ground pattern 132, the first power pattern 134, and the first signal pattern 136 may be separated and electrically insulated from one another by the first redistribution insulating layer 102.

Referring to FIGS. 2A, 2B, and 3B, a second adjacent redistribution layer 230n closest to the conductive blocks 160 among the second redistribution layers 230 may be at the third vertical level LV3. According to an embodiment, the second redistribution patterns 212 of the second adjacent redistribution layer 230n may include a second ground pattern 232, a second power pattern 234, and a second signal pattern 236. According to an embodiment, the second ground pattern 232, the second power pattern 234, and the second signal pattern 236 may be separated and electrically insulated from one another by the second redistribution insulating layer 202.

According to an embodiments, the opposite ends of each of some of the first redistribution vias 114 in the vertical direction (e.g., the Z direction) may be respectively in direct contact with the first adjacent redistribution layer 130n and one of the lower block pads 124a. The conductive blocks 160 may be electrically connected to the first adjacent redistribution layer 130n through the lower block pads 124a and the first redistribution vias 114. According to an embodiment, the opposite ends of each of some of the second redistribution vias 214 in the vertical direction (e.g., the Z direction) may be respectively in direct contact with the second adjacent redistribution layer 230n and one of the upper block pads 222a. The conductive blocks 160 may be electrically connected to the second adjacent redistribution layer 230n through the upper block pads 222a and the second redistribution vias 214.

According to an embodiment, a ground voltage may be applied to the first and second ground patterns 132 and 232 and a power voltage may be applied to the first and second power patterns 134 and 234. In an embodiment, a signal voltage for transmitting and receiving an input/output (I/O) data signal and a control signal, such as a command signal, may be applied to the first and second signal patterns 136 and 236.

In some embodiments, according to a plan view, each of the first and second ground patterns 132 and 232 may have a planar shape. For example, the first ground pattern 132 may be between the first power pattern 134 and the first signal pattern 136 and may extend in the horizontal direction (e.g., the X direction and/or the Y direction) to horizontally surround each of the first power pattern 134 and the first signal pattern 136. For example, the second ground pattern 232 may be between the second power pattern 234 and the second signal pattern 236 and may extend in the horizontal direction (e.g., the X direction and/or the Y direction) to horizontally surround each of the second power pattern 234 and the second signal pattern 236. In some embodiments, according to a plan view, each of the first and second ground patterns 132 and 232 may have a line or dot shape.

In some embodiments, according to a plan view, each of the first and second power patterns 134 and 234 may have a line shape. In some embodiments, according to a plan view, each of the first and second signal patterns 136 and 236 may have a line shape. In some embodiments, each of the first and second power patterns 134 and 234 and the first and second signal patterns 136 and 236 may have a critical dimension (CD) that is perpendicular to the extension direction of each of the first and second power patterns 134 and 234 and the first and second signal patterns 136 and 236. In some embodiments, the first and second power patterns 134 and 234 may have a first CD and the first and second signal patterns 136 and 236 may have a second CD. In some embodiments, the first CD may be greater than the second CD. For example, in some embodiments, the first CD may be in a range of about 30 nm to about 70 nm and the second CD may be in a range of about 1 nm to about 25 nm. However, embodiments of the present inventive concept are not necessarily limited thereto.

Referring to FIG. 3C, each of the first and second signal patterns 136 and 236 may include a signal pair pattern SPP, which includes two signal lines SL extending to be parallel with each other. In an embodiment, the two signal lines SL may be close to each other and separated from each other by the first redistribution insulating layer 102 or the second redistribution insulating layer 202. The two signal lines SL may increase signal exchange speed and efficiency through signal coupling.

In some embodiments, each signal line SL may include an extension part EP and two landing parts LP respectively connected to the opposite ends of the extension part EP. In some embodiments, each landing part LP may have a pad shape having a horizontal width that is greater than the CD of the extension part EP. Although it is illustrated in FIG. 3C that each landing part LP has a circular planar shape (e.g., in a plane defined in the X and Y directions), embodiments of the present inventive concept are not necessarily limited thereto.

In some embodiments, the extension part EP of the signal line SL may extend in the horizontal direction (e.g., the X direction and/or the Y direction). In some embodiments, the signal line SL may include a straight line and/or a bent portion.

In some embodiments, each of the landing parts LP of the signal line SL may be in direct contact with a first redistribution via 114 or a second redistribution via 214. For example, in an embodiment each signal line SL of the first signal pattern 136 may include two landing parts LP. The top surface of one of the two landing parts LP may be in direct contact with a first redistribution via 114 that is at a higher vertical level than the signal line SL, and the bottom surface of the other landing part LP may be in direct contact with a first redistribution via 114 that is at a lower vertical level than the signal line SL. Similarly, each signal line SL of the second signal pattern 236 may include two landing parts LP, which are respectively in direct contact with and directly connected to second redistribution vias 214 respectively at different vertical levels.

In some embodiments, each of the first and second signal patterns 136 and 236 may include a plurality of signal pair patterns SPP. In this embodiment, the signal pair patterns SPP may be separated from each other by the first redistribution insulating layer 102 or the second redistribution insulating layer 202.

According to an embodiment, the conductive blocks 160 may include a heat dissipation block 162, a power block 164, and a shielding block 166.

According to an embodiment, the second semiconductor chip 20 may have a heating area HA according to a plan view. For example, the heating area HA may refer to an area that has a higher temperature than the remaining areas in the second semiconductor chip 20.

According to an embodiment, the heat dissipation block 162 may overlap the heating area HA of the second semiconductor chip 20 in the vertical direction (e.g., the Z direction), thereby providing a heat dissipation path. In some embodiments, according to a plan view, the heating area HA may be within the outer boundary of the heat dissipation block 162. For example, in an embodiment the heat dissipation block 162 may have a plate shape or a wall shape and have a relatively large planar area (e.g., in a plane defined in the X and Y directions) to cover the heating area HA. Accordingly, the heat of the second semiconductor chip 20 may flow in the vertical direction (e.g., the Z direction) through the heat dissipation block 162, and thus, the heat dissipation characteristic of the semiconductor package 1000 may increase.

In some embodiments, the heat dissipation block 162 may overlap at least a portion of the first ground pattern 132 and/or at least a portion of the second ground pattern 232 in the vertical direction (e.g., the Z direction). In some embodiments, the heat dissipation block 162 may be electrically connected to the first ground pattern 132 and/or the second ground pattern 232. For example, in an embodiment the heat dissipation block 162 may be electrically connected to the first ground pattern 132 of the first adjacent redistribution layer 130n through some of the lower block pads 124a and some of the first redistribution vias 114. For example, the heat dissipation block 162 may be electrically connected to the second ground pattern 232 of the second adjacent redistribution layer 230n through some of the upper block pads 222a and some of the second redistribution vias 214. For example, the heat dissipation block 162, the first ground pattern 132, and the second ground pattern 232 may provide a heat dissipation path for discharging the heat of the heating area HA of the second semiconductor chip 20.

In some embodiments, some of the second chips 24 and some of the second chip connectors 26 may vertically overlap the heating area HA of the second semiconductor chip 20. Accordingly, the heat of the second semiconductor chip 20 may be easily transmitted (e.g., in the Z direction) to the first ground pattern 132, the heat dissipation block 162, and the second ground pattern 232.

According to an embodiment, the first power pattern 134 may be electrically connected to the second power pattern 234 through the power block 164. For example, in an embodiment the power block 164 may be electrically connected to the first power pattern 134 of the first adjacent redistribution layer 130n through some of the lower block pads 124a and some of the first redistribution vias 114. For example, the power block 164 may be electrically connected to the second power pattern 234 of the second adjacent redistribution layer 230n through some of the upper block pads 222a and some of the second redistribution vias 214. In some embodiments, the power block 164 may overlap at least a portion of the first power pattern 134 and/or at least a portion of the second power pattern 234 in the vertical direction (e.g., the Z direction).

In some embodiments, the power block 164 may have a plate shape and have a larger planar area (e.g., in a plane defined in the X and Y directions) than each of the conductive posts 152. According to an embodiment, the power block 164 may efficiently transmit power between the first redistribution structure 100 and the second redistribution structure 200 via the relatively large volume of the power block 164, and thus, the power integrity of the semiconductor package 1000 may be increased.

In some embodiments, the same voltage may be applied to the first power pattern 134 and the second power pattern 234. For example, the semiconductor package 1000 may include a plurality of power blocks 164. In this embodiment, different power voltages may be respectively applied to at least some of the power blocks 164.

According to an embodiment, the conductive blocks 160 may include a plurality of shielding blocks 166. The shielding blocks 166 may overlap at least some of a plurality of first signal patterns 136 and/or at least some of a plurality of second signal patterns 236 in the vertical direction (e.g., the Z direction). In some embodiments, each of the shielding blocks 166 may have a line shape in correspondence to the horizontal cross-section of a first signal pattern 136 vertically overlapping each shielding block 166 and/or the horizontal cross-section of a second signal pattern 236 vertically overlapping each shielding block 166. For example, in an embodiment the shielding block 166 may have a wall shape that extends longitudinally in the horizontal direction (e.g., the X direction and/or the Y direction).

In some embodiments, the shielding block 166 may vertically overlap the first signal pattern 136 and the second signal pattern 236. In some embodiments, according to a plan view, the first signal pattern 136 and the second signal pattern 236 may be within the outer boundary of the shielding block 166. In some embodiments, the shielding block 166 may be electrically insulated from the first signal pattern 136 and the second signal pattern 236. However, embodiments of the present inventive concept are not necessarily limited thereto. For example, in some embodiments, the shielding block 166 may be electrically connected to the first ground pattern 132 and/or the second ground pattern 232. For example, the shielding block 166 may be electrically connected to the first ground pattern 132 of the first adjacent redistribution layer 130n through some of the lower block pads 124a and some of the first redistribution vias 114. For example, the shielding block 166 may be electrically connected to the second ground pattern 232 of the second adjacent redistribution layer 230n through some of the upper block pads 222a and some of the second redistribution vias 214.

A ground voltage may be applied to the shielding block 166, and accordingly, signal integrity is prevented from degrading due to coupling between the first signal pattern 136 and the second signal pattern 236 in the vertical direction (e.g., in the Z direction).

In some embodiments, one of the plurality of shielding blocks 166 (hereinafter referred to as the first shielding block 166) may vertically overlap a first signal pair pattern SPP selected from among the plurality of first signal patterns 136 and a second signal pair pattern SPP selected from among the plurality of second signal patterns 236. For example, according to a plan view, the first signal pair pattern SPP and the second signal pair pattern SPP may be within the outer boundary of the first shielding block 166.

Although it is illustrated in FIGS. 3A, 3B, 4A, and 4B that each of the shielding blocks 166 vertically overlaps a first signal pattern 136 and a second signal pattern 236 in units of signal pair patterns SPP, embodiments of the present inventive concept are not necessarily limited thereto. For example, each shielding block 166 may vertically overlap at least two signal pair patterns SPP. For example, one shielding block 166 may vertically overlap a plurality of first signal pair patterns SPP and a plurality of second signal pair patterns SPP. According to a plan view, the first signal pair patterns SPP and the second signal pair patterns SPP may be within the boundary of the shielding block 166. In this embodiment, the shielding block 166 may have a plate shape.

Although it is illustrated in FIGS. 3A, 3B, 4A, and 4B that the first signal pattern 136 and the second signal pattern 236 overlap each other in the vertical direction (e.g., the Z direction) only in the landing parts LP of the signal pair patterns SPP, embodiments of the present inventive concept are not necessarily limited thereto. For example, the first signal pattern 136 and the second signal pattern 236 may extend in independent directions, and the extension part EP (FIG. 3C) of the first signal pattern 136 may overlap the extension part EP of the second signal pattern 236 in the vertical direction (e.g., the Z direction). For example, the first signal pair pattern SPP of the first signal pattern 136 may overlap the second signal pair pattern SPP of the second signal pattern 236 in the vertical direction (e.g., the Z direction).

In some embodiments, each of the shielding blocks 166 may include a first part 166a, which vertically overlaps the first signal pattern 136, and a second part 166b, which vertically overlaps the second signal pattern 236. In some embodiments, the first part 166a of the shielding block 166 may be spaced apart from the first signal pattern 136 in the vertical direction (e.g., the Z direction) and may horizontally extend along the first signal pattern 136. The second part 166b of the shielding block 166 may be spaced apart from the second signal pattern 236 in the vertical direction (e.g., the Z direction) and may horizontally extend along the second signal pattern 236.

In some embodiments, the conductive posts 152 may include a plurality of signal posts 152a, which electrically connect the first signal pattern 136 to the second signal pattern 236. For example, the signal posts 152a may transmit signals between the first signal pattern 136 and the second signal pattern 236. In some embodiments, the signal posts 152a may be respectively disposed in a plurality of vertical holes CBH, which pass through the shielding block 166 in the vertical direction (e.g., the Z direction). In an embodiment, the signal posts 152a may be separated from the shielding block 166 by the encapsulation material 170 and surrounded by the shielding block 166. In some embodiments, each shielding block 166 may include a portion between two adjacent signal posts 152a.

In some embodiments, two signal posts 152a may be surrounded by one shielding block 166 and connected to the signal pair pattern SPP of the first signal pattern 136 and the signal pair pattern SPP of the second signal pattern 236. However, embodiments of the present inventive concept are not necessarily limited thereto. For example, in an embodiment, in a plan view (e.g., in a plane defined in the X and Y directions), one signal post 152a or at least three signal posts 152a may be surrounded by one shielding block 166 and connected to one or at least three signal lines SL of the first signal pattern 136 and one or at least three signal lines SL of the second signal pattern 236.

In some embodiments, the signal posts 152a may be in a portion of the shielding block 166, in which the first part 166a and the second part 166b of the shielding block 166 intersect or meet with each other. In some embodiments, an end of each of the signal posts 152a in the vertical direction (e.g., the Z direction) may be connected to the first signal pattern 136 and the other end of each signal post 152a in the vertical direction (e.g., the Z direction) may be connected to the second signal pattern 236. For example, respective portions of a first landing part LP and a second landing part LP of the first signal pattern 136 may vertically overlap the signal posts 152a, respectively, and may be respectively aligned with the signal posts 152a in the vertical direction (e.g., the Z direction).

In some embodiments, an end of each of the signal posts 152a may be connected to a portion of the first landing part LP of the first signal pattern 136 through a first top connection pad 124 and a first redistribution via 114 and the other end of each signal post 152a may be connected to a portion of the second landing part LP of the second signal pattern 236 through a second bottom connection pad 222 and a second redistribution via 214.

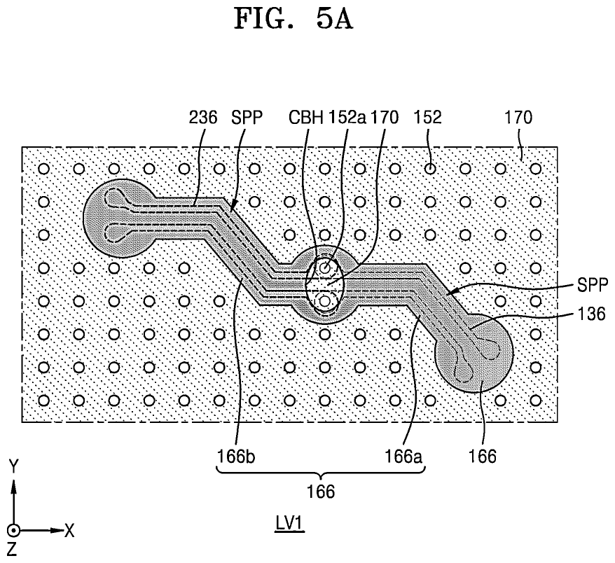

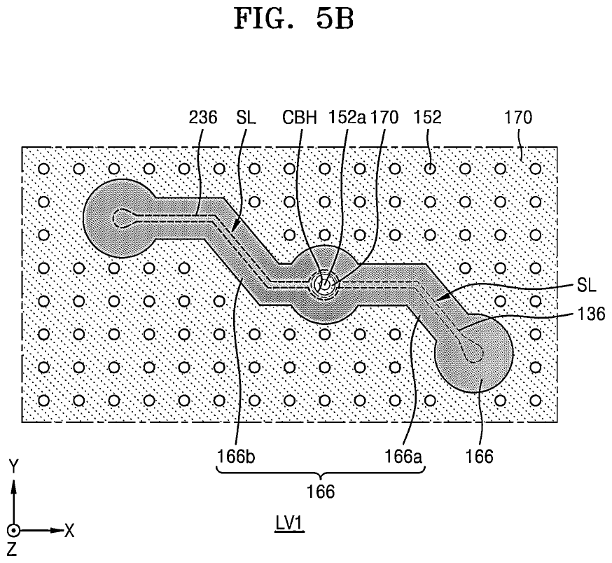

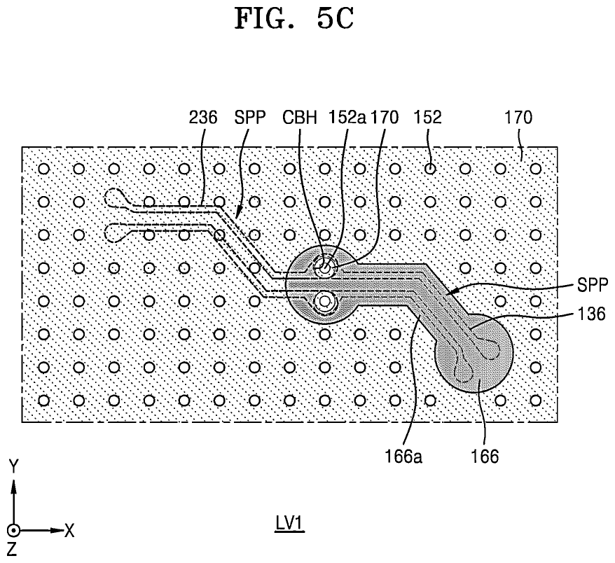

FIGS. 5A to 5C are partial plan views illustrating configurations of the semiconductor package 1000 of FIGS. 1 to 2B at the first vertical level LV1 in FIGS. 2A and 2B, according to some embodiments. In detail, FIGS. 5A to 5C illustrate the shielding block 166 and a configuration around the shielding block 166, according to some embodiments.

Referring to FIG. 5A, unlike what is shown in FIG. 4A, a plurality of signal posts 152a may be disposed in a single vertical hole CHB. In some embodiments, the signal posts 152a in the single vertical hole CHB may be separated from each other by the encapsulation material 170. In this embodiment, the shielding block 166 may not be between the signal posts 152a.

In some embodiments, two signal posts 152a may be in the single vertical hole CHB. However, embodiments of the present inventive concept are not necessarily limited thereto. For example, one or at least three signal posts 152a may be in the single vertical hole CHB and surrounded by the shielding block 166.

Referring to FIG. 5B, unlike what is illustrated in FIG. 4A, each of some of a plurality of shielding blocks 166 may vertically overlap a first signal line SL of a first signal pattern 136 and a second signal line SL of a second signal pattern 236. In some embodiments, one signal post 152a may extend in the vertical direction (e.g., the Z direction) through one shielding block 166. One end of the signal post 152a may be connected to the first signal line SL of the first signal pattern 136 and the other end of the signal post 152a may be connected to the second signal line SL of the second signal pattern 236.

Referring to FIG. 5C, unlike what is illustrated in FIG. 4A, each of some of a plurality of shielding blocks 166 may vertically overlap only a first signal pair pattern SPP of a first signal pattern 136 but not a second signal pair pattern SPP of a second signal pattern 236. In some embodiments, each of some of a plurality of shielding blocks 166 may vertically overlap only the second signal pair pattern SPP of the second signal pattern 236 but not the first signal pair pattern SPP of the first signal pattern 136.

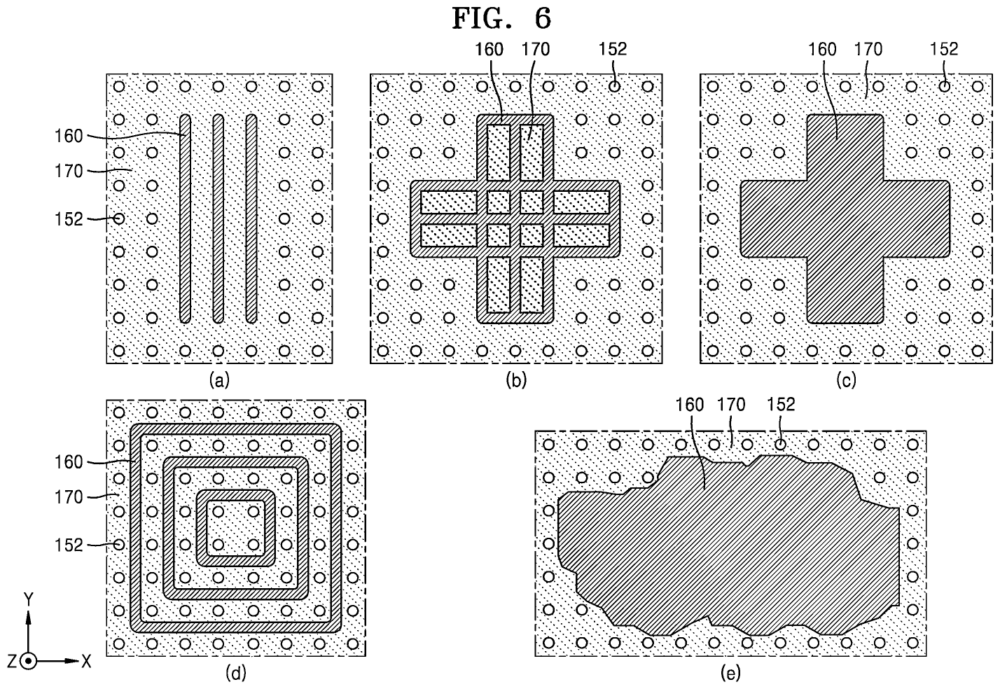

FIG. 6 shows partial plan views illustrating configurations of the semiconductor package 1000 at the first vertical level LV1 in FIGS. 2A and 2B, according to some embodiments. In detail, FIG. 6 illustrates conductive blocks 160 and configurations around the conductive blocks 160, according to some embodiments.

Referring to (a) of FIG. 6, each of some of a plurality of conductive blocks 160 may have a line shape extending in a straight line, according to a plan view. For example, the conductive blocks 160 may extend in the second horizontal direction (e.g., the Y direction) to be parallel with each other and may be spaced apart from each other in the first horizontal direction (e.g., the X direction). In some embodiments, the conductive blocks 160 may be separated from each other by the encapsulation material 170. The conductive blocks 160 may be close to each other and surrounded by a plurality of conductive posts 152, according to a plan view (e.g., in a plane defined in the X and Y directions).

Referring to (b) of FIG. 6, each of some of the conductive blocks 160 may include a plurality of internal spaces, according to a plan view (e.g., in a plane defined in the X and Y directions). For example, the encapsulation material 170 may be disposed in the internal spaces. In some embodiments, the internal spaces may have different planar areas. In some embodiments, each conductive block 160 may include a part between the internal spaces and a part surrounding the internal spaces. In some embodiments, according to a plan view, the conductive block 160 may extend in a line and have a cross-shaped outer boundary.

Referring to (c) of FIG. 6, each of some of the conductive blocks 160 may have a cross-shaped horizontal cross-section. Compared to (b) of FIG. 6, each conductive block 160 may have a solid planar shape without an internal space, according to a plan view (e.g., in a plane defined in the X and Y directions).

Referring to (d) of FIG. 6, according to a plan view, the conductive blocks 160 may respectively have hollow quadrangular shapes, which share a center and have different distances from the center. For example, each of the conductive blocks 160 may have a wall shape and extend in the horizontal direction (e.g., the X direction and/or the Y direction). In some embodiments, the conductive blocks 160 each having a quadrangular shape may be spaced apart from each other. A plurality of conductive posts 152 may be disposed between the conductive blocks 160. In this embodiment, the encapsulation material 170 may be disposed between the conductive blocks 160 and between the conductive blocks 160 and the conductive posts 152.

Although it is illustrated in (d) of FIG. 6 that each of the conductive blocks 160 has a hollow quadrangular planar shape, embodiments of the present inventive concept are not necessarily limited thereto. For example, in some embodiments the conductive blocks 160 may respectively have hollow concentric circular or triangular shapes.

Referring to (e) of FIG. 6, each of some of the conductive blocks 160 may have an irregular outer boundary, according to a plan view. For example, each conductive block 160 may include at least three parts, which respectively have different widths in the second horizontal direction (e.g., the Y direction), while extending in the first horizontal direction (e.g., the X direction) and may include at least three parts, which respectively have different widths in the first horizontal direction (e.g., the X direction), while extending in the second horizontal direction (e.g., the Y direction). For example, the conductive block 160 in (c) of FIG. 6 may correspond to the heat dissipation block 162 in FIG. 1 and have an irregular planar shape corresponding to the irregular heating area HA of the second semiconductor chip 20. In some embodiments, the conductive block 160 having the irregular planar shape may have internal spaces having the encapsulation material 170 disposed therein.

While the present inventive concept has been particularly shown and described with reference to non-limiting embodiments thereof, it will be understood that various changes in form and details may be made therein without departing from the spirit and scope of the present inventive concept.

What is claimed is:

1. A semiconductor package comprising:
a first redistribution structure comprising a plurality of first redistribution layers;
a second redistribution structure above the first redistribution structure, the second redistribution structure comprising a plurality of second redistribution layers;
a first semiconductor chip on the first redistribution structure and arranged between the first redistribution structure and the second redistribution structure;
a conductive block directly contacting the first redistribution structure and the second redistribution structure and extending in a horizontal direction between the first redistribution structure and the second redistribution structure; and
a plurality of conductive posts around the first semiconductor chip and the conductive block, the plurality of conductive posts extending in a vertical direction and directly contacting the first redistribution structure and the second redistribution structure.

2. The semiconductor package of claim 1, wherein,
in a plan view, each of the plurality of conductive posts has a dot shape and the conductive block has a planar shape.

3. The semiconductor package of claim 1, wherein:
the plurality of first redistribution layers comprises a first adjacent redistribution layer positioned closest to the first semiconductor chip among the plurality of first redistribution layers;
the first adjacent redistribution layer comprises a first signal pattern; and
the conductive block overlaps the first signal pattern in the vertical direction.

4. The semiconductor package of claim 3, wherein,
in a plan view, the conductive block has a line shape.

5. The semiconductor package of claim 3, wherein the conductive block is electrically insulated from the first signal pattern.

6. The semiconductor package of claim 3, wherein:
the first adjacent redistribution layer further comprises a first ground pattern; and
the conductive block is electrically connected to the first ground pattern.

7. The semiconductor package of claim 3, further comprising:
a vertical hole passing through the conductive block in the vertical direction,
wherein the plurality of conductive posts comprises a first conductive post electrically connected to the first signal pattern, the first conductive post is disposed in the vertical hole and is spaced apart from the conductive block.

8. The semiconductor package of claim 2, wherein:
the plurality of second redistribution layers comprises a second adjacent redistribution layer positioned closest to the first semiconductor chip among the plurality of second redistribution layers;
the second adjacent redistribution layer comprises a second signal pattern; and
the conductive block overlaps the second signal pattern in the vertical direction.

9. The semiconductor package of claim 1, further comprising:
a second semiconductor chip on the second redistribution structure, the second semiconductor chip comprising a heating area,
wherein the conductive block overlaps the heating area in the vertical direction.

10. The semiconductor package of claim 9, wherein:
the plurality of first redistribution layers comprises a first adjacent redistribution layer positioned closest to the first semiconductor chip among the plurality of first redistribution layers,
the first adjacent redistribution layer comprises a first ground pattern; and
the conductive block is electrically connected to the first ground pattern.

11. A semiconductor package comprising:
a first redistribution structure comprising a first redistribution pattern comprising a first ground pattern, a first power pattern, and a first signal pattern;
a second redistribution structure above the first redistribution structure, the second redistribution structure comprising a second redistribution pattern comprising a second ground pattern, a second power pattern, and a second signal pattern;
a first semiconductor chip on the first redistribution structure and arranged between the first redistribution structure and the second redistribution structure;
a second semiconductor chip on the second redistribution structure and comprising a heating area;
a plurality of conductive blocks each having a wall shape extending in a horizontal direction between the first redistribution structure and the second redistribution structure, the plurality of conductive blocks directly contacting the first redistribution structure and the second redistribution structure;
a plurality of conductive posts around the first semiconductor chip and the plurality of conductive blocks, the plurality of conductive posts directly contacting the first redistribution structure and the second redistribution structure, the plurality of conductive posts each having a pillar shape extending in a vertical direction; and
an encapsulation material between the first redistribution structure and the second redistribution structure, the encapsulation material surrounding the first semiconductor chip, the plurality of conductive blocks, and the plurality of conductive posts.

12. The semiconductor package of claim 11, wherein:
the first signal pattern comprises a first signal pair pattern comprising two first signal lines extending in parallel with each other; and
a first conductive block among the plurality of conductive blocks vertically overlaps the first signal pair pattern.

13. The semiconductor package of claim 12, wherein:
in a plan view, the first conductive block has a line shape and is surrounded by the plurality of conductive posts each having a dot shape.

14. The semiconductor package of claim 11, wherein:
the first signal pattern comprises a first signal pair pattern comprising two first signal lines extending in parallel with each other;
the second signal pattern comprises a second signal pair pattern comprising two second signal lines extending in parallel with each other;
the plurality of conductive posts comprises a plurality of signal posts electrically connecting the first signal pattern to the second signal pattern; and
some of the plurality of signal posts are aligned with both of the first signal pair pattern and the second signal pair pattern in the vertical direction.

15. The semiconductor package of claim 14, wherein:
a first conductive block among the plurality of conductive blocks comprises a plurality of vertical holes passing therethrough in the vertical direction; and
the plurality of signal posts are respectively disposed in the plurality of vertical holes.

16. The semiconductor package of claim 15, wherein
the encapsulation material is disposed in the plurality of vertical holes, and
the plurality of signal posts are spaced apart from the first conductive block with the encapsulation material disposed directly therebetween.

17. A semiconductor package comprising:
a first redistribution structure comprising a first redistribution pattern comprising a first ground pattern, a first power pattern, and a first signal pattern;
a second redistribution structure above the first redistribution structure, the second redistribution structure comprising a second redistribution pattern comprising a second ground pattern, a second power pattern, and a second signal pattern;
a first semiconductor chip on the first redistribution structure and arranged between the first redistribution structure and the second redistribution structure;
a second semiconductor chip on the second redistribution structure and comprising a heating area;
a plurality of conductive blocks extending in a horizontal direction between the first redistribution structure and the second redistribution structure, the plurality of conductive blocks directly contacting the first redistribution structure and the second redistribution structure, the plurality of conductive blocks comprising a heat dissipation block, a power block, and a shielding block; and
a plurality of conductive posts around the first semiconductor chip and the plurality of conductive blocks, the plurality of conductive posts extending in a vertical direction and directly contacting the first redistribution structure and the second redistribution structure.

18. The semiconductor package of claim 17, wherein:
the power block at least partially overlaps the first power pattern and the second power pattern in the vertical direction; and
the power block is electrically connected to the first power pattern and the second power pattern.

19. The semiconductor package of claim 17, wherein:
the heat dissipation block vertically overlaps the heating area of the second semiconductor chip; and
the heating area of the second semiconductor chip is positioned within the heat dissipation block in a plan view.

20. The semiconductor package of claim 17, wherein:
the shielding block vertically overlaps and is electrically insulated from the first signal pattern and the second signal pattern; and
the shielding block is electrically connected to the first ground pattern and the second ground pattern.
